(19) United States
(12) Patent Application Publication
(10) Pub. No.: US 2009/0085093 A1
(43) Pub. Date: Apr. 2, 2009

(54) SEMICONDUCTOR DEVICES AND METHOD OF FABRICATING THE SAME

(76) Inventor: Haeng-Leem Jeon, Anyang-si (KR)

Correspondence Address: SHERR & VAUGHN, PLLC, 620 HERNDON PARKWAY, SUITE 200, HERNDON, VA, 20170, US

(21) Appl. No.: 12/233,643

(22) Filed: Sep. 19, 2008

(30) Foreign Application Priority Data
Sep. 27, 2007 (KR) 10-2007-0097296

(51) Int. Cl. H01L 29/788; H01L 21/3205

(52) U.S. Cl. 257/316; 438/593; 257/E29.3

(57) ABSTRACT

A semiconductor device and a fabricating method thereof are provided. The semiconductor device fabricating method includes forming a nitride layer pattern over a semiconductor substrate, forming a trench by etching the semiconductor substrate using the nitride layer pattern as a mask, forming a first insulation layer over an entire face of the semiconductor substrate, forming a device isolation pattern by polishing the first insulation layer to expose the nitride layer pattern, removing the nitride layer pattern, forming a first polysilicon layer over an entire face of the semiconductor substrate, etching the first polysilicon layer to expose the device isolation pattern and thus forming a floating gate electrode between the device isolation patterns, forming a second insulation layer covering the floating gate electrode, forming a second polysilicon layer over the insulation layer, and patterning the second polysilicon layer and the second insulation layer and thus forming a control gate electrode and a second insulation layer pattern.

The present application claims priority under 35 U.S.C. 119 to Korean Patent Application No. 10-2007-0097296 (filed on Sep. 27, 2007), which is hereby incorporated by reference in its entirety.

### BACKGROUND

Semiconductor memory devices may be largely classified as volatile memory and nonvolatile memory. The volatile memory is mainly RAM such as DRAM (Dynamic Random Access Memory), SRAM (Static Random Access Memory) etc. Volatile memory has the property of allowing data to be input and stored when power is applied, but losing the data when power is interrupted. The nonvolatile memories are mainly ROM (Read Only Memory) and have the property of allowing data to be preserved even when power is not applied.

In the present process technology, nonvolatile memory devices may be further classified into a floating gate group and a metal insulator semiconductor (MIS) group. Within these technologies, there is a difficulty in aligning active areas and floating gates with the increasingly higher level of integration of semiconductor devices, causing a degradation in device properties.

### SUMMARY

Embodiments relate to a semiconductor device having an increased coupling ratio between a floating gate electrode and a control gate electrode. Embodiments relate to a method of fabricating a semiconductor device using a self alignment floating gate process.

Embodiments relate to a method of fabricating a semiconductor device which includes forming a nitride layer pattern over a semiconductor substrate, forming a trench by etching the semiconductor substrate using the nitride layer pattern as a mask, forming a first insulation layer over an entire face of the semiconductor substrate, forming a device isolation pattern by polishing the first insulation layer to expose the nitride layer pattern, removing the nitride layer pattern, forming a first polysilicon layer over an entire face of the semiconductor substrate, etching the first polysilicon layer to expose the device isolation pattern and thus forming a floating gate electrode between the device isolation patterns, forming a second insulation layer covering the floating gate electrode, forming a second polysilicon layer over the insulation layer, and patterning the second polysilicon layer and the second insulation layer and thus forming a control gate electrode and a second insulation layer pattern.

Embodiments relate to a semiconductor device which includes a device isolation pattern defining an active area on a semiconductor substrate. A floating gate electrode may be formed over the active area. An upper face of the floating gate electrode may be recessed. An insulation layer pattern may be formed over the recessed upper face of the floating gate electrode. A control gate electrode may be formed over the insulation layer pattern.

As described above, according to embodiments, a manufacturing process may be simplified, a production yield increases and manufacturing costs are reduced. In addition, according to embodiments, a floating gate electrode may be formed through a self alignment scheme, thereby preventing misalignment and improving a thinning effect by reducing the depth of divot between a device isolation pattern and an active area. This increases reliability of the device and lowers the defect rate.

### DRAWINGS

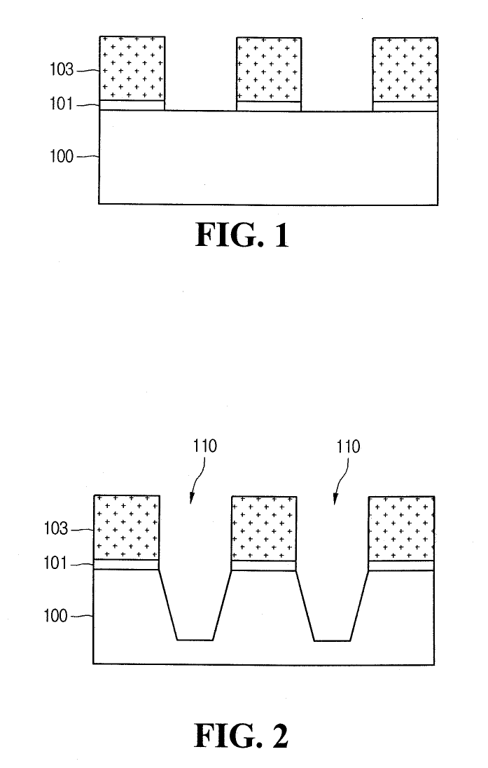

Example FIGS. 1 through 9 are sectional views illustrating a fabrication method of semiconductor devices according to embodiments.

### DESCRIPTION

Example FIGS. 1 to 9 are sectional views illustrating a semiconductor device fabricating method according to embodiments. As shown in example FIG. 1, an oxide layer pattern 101 and a nitride layer pattern 103 may be formed over a semiconductor substrate 100 formed of a base of silicon (Si). The oxide layer pattern 101 and the nitride layer pattern 103 may be formed by forming an oxide layer over the semiconductor substrate 100 and forming a nitride layer over the oxide layer. A photolithography process may be used to pattern the nitride layer and the oxide layer. The thickness of the oxide layer pattern 101 and the nitride layer pattern 103 may be approximately 1000 Å to 1500 Å. The oxide layer 101a may be formed by using a thermal oxidation or deposition method.

With reference to example FIG. 2, the semiconductor substrate 100 may be etched to a given depth using the oxide layer pattern 101 and the nitride layer pattern 103 as a mask, thereby forming trench 110. The trench 110 may be formed by a dry etching process such as a reactive ion etching (RIE). In a dry etching process, energy may be applied to accelerate ions. The ions are directed at and collide with the semiconductor substrate 100, thereby removing silicon atoms from the semiconductor substrate 100. As a result, on a trench formation area of the semiconductor substrate 100, a trench 110 with a given depth may be formed. The trench defines an active area on which devices are formed over the semiconductor substrate. The oxide layer pattern 101 and the nitride layer pattern 103 may remain over the semiconductor substrate 100.

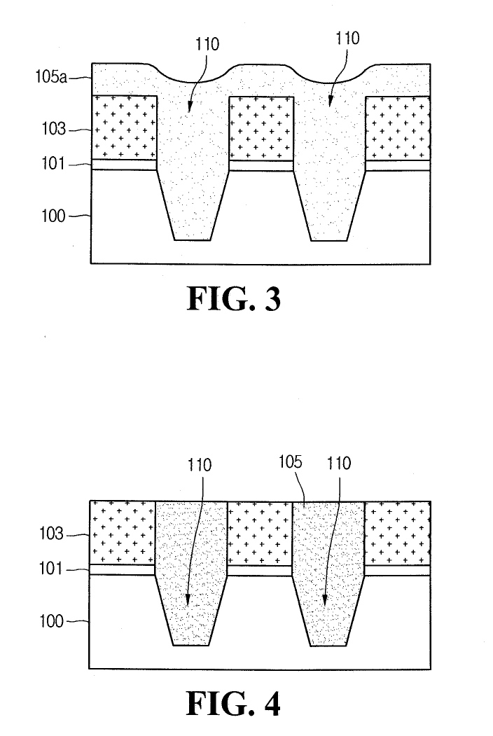

Referring to example FIG. 3, an insulation layer 105a may be formed over the semiconductor substrate 100 over which the oxide layer pattern 101, the nitride layer pattern 103 and the trench 110 have been formed. The insulation layer 105a fills the trench 110 to the given depth. The insulation layer 105a may be formed through an HDP-CVD (high density plasma chemical vapor deposition). The insulation layer 105a may be an oxide layer. A top face of the insulation layer 105a may not be planarized by a step coverage of the semiconductor substrate 100 with the trench 110.

As shown in example FIG. 4, a top face of the insulation layer 105a may be polished and planarized through a chemical mechanical polishing to expose the nitride layer pattern 103. Here, the nitride layer pattern 103 may be used as an etch stop layer of the chemical mechanical polishing. The insulation layer pattern 103 may be formed within the trench 110, thus forming a device isolation pattern 105. The device isolation pattern 105 may be, i.e., shallow trench isolation pattern. The device isolation pattern 105 may protrude 1000 Å to 1500 Å from the semiconductor substrate 100.

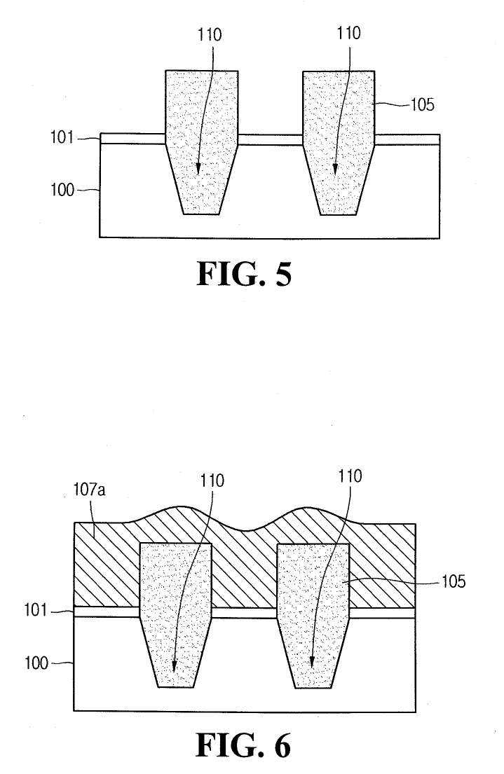

As shown in example FIGS. 5 and 6, the nitride layer pattern 103 may be removed. First polysilicon layer 107a may be formed over an entire face of the semiconductor substrate 100. The first polysilicon layer 107a may be a floating gate formation material, and may be formed with a sufficient thickness to cover the device isolation pattern 105 and the oxide layer pattern 101.

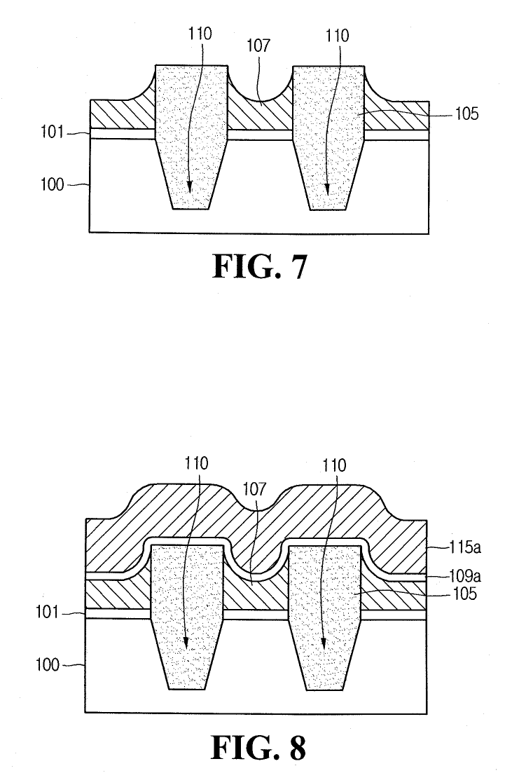

As shown in example FIG. 7, an entire face of the first polysilicon layer 107a may be bulk etched. The bulk etching may be performed through a dry etching process such as RIE process. A floating gate electrode 107 may be formed by etching an entire face of the first polysilicon layer 107a until a top face of the device isolation pattern 105 is exposed. The floating gate electrode 107 may be formed over an active area between different portions of the device isolation pattern 105. An upper face of the floating gate electrode 107 is lower than an upper face of the device isolation pattern 105.

The first polysilicon layer 107a may be anisotropically etched and thus the first polysilicon layer 107a may remain in a sidewall of the device isolation pattern. That is, the dry etching process is an anisotropic etching method that has a greater etching rate in a direction vertical to the substrate than an etching rate in a horizontal direction. Thus the first polysilicon layer 107a between the device isolation patterns 105 is etched at a faster rate in a center area than in an edge region. An upper face of the floating gate electrode 107 may have a U shape between the device isolation patterns 105.

A portion of the device isolation pattern 105 may be etched. When a portion of the device isolation pattern 105 is etched, a top of the device isolation pattern 105 may be lower than a top of the floating gate electrode 107.

According to embodiments, floating gate electrode 107 may be formed through a self alignment scheme, using the device isolation pattern 105 without a mask process and polishing process. Thus, the process may be advantageously simplified, and pattern defects caused by mask misalignment can be prevented.

In addition, in embodiments, device isolation pattern 105 and floating gate electrode 107 are formed through the self alignment scheme, thus a thinning effect is improved by reducing the depth of divot between the device isolation pattern 105 and the active area. This reduces leakage current and increases device reliability.

As shown in example FIG. 8, an oxide-nitride-oxide layer (hereinafter, referred to as an ‘ONO layer’) may be sequentially deposited over the semiconductor substrate 100 including the device isolation pattern 105 and the floating gate electrode 107, thereby forming an ONO layer 109a. The ONO layer 109a may be formed with an even thickness along a recessed upper face of the floating gate electrode 107. A second polysilicon layer 115a may be formed by depositing polysilicon over the ONO layer 109a.

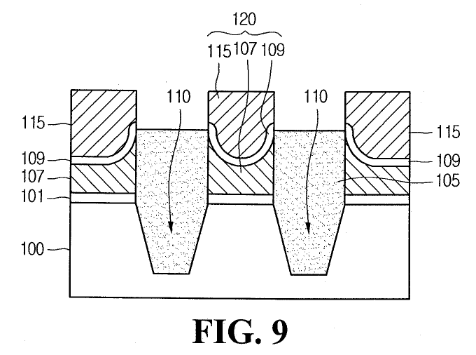

With reference to example FIG. 9, an ONO pattern 109 and a control gate electrode 115 may be formed over the floating gate electrode 107 by patterning the second polysilicon layer 115a and the ONO layer 109a. As a result, a gate stack 120 comprised of the floating gate electrode 107, ONO pattern 109 and control gate electrode 115 may be formed over active area formed on the semiconductor substrate 100.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a nitride layer pattern over a semiconductor substrate;
forming a trench by etching the semiconductor substrate using the nitride layer pattern as a mask;
forming a first insulation layer over an entire face of the semiconductor substrate;
forming device isolation patterns by polishing the first insulation layer to expose the nitride layer pattern;
removing the nitride layer pattern;
forming a first polysilicon layer over an entire face of the semiconductor substrate;
etching the first polysilicon layer to expose the device isolation patterns, thus forming a floating gate electrode between the device isolation patterns;
forming a second insulation layer covering the floating gate electrode;
forming a second polysilicon layer over the second insulation layer; and
patterning the second polysilicon layer and the second insulation layer and thus forming a control gate electrode and a second insulation layer pattern.

2. The method of claim 1, wherein said etching the first polysilicon layer uses dry etching.

3. The method of claim 1, wherein in said etching the first polysilicon layer to expose the device isolation patterns and thus forming a floating gate electrode between the device isolation patterns, a height of center portion of the floating gate electrode is lower than a height of edge portion thereof, and the height of the edge portion is lower than a height of the device isolation patterns.

4. The method of claim 1, comprising removing a portion of the device isolation patterns after said forming the floating gate electrode.

5. The method of claim 1, wherein the second insulation layer is formed by successively depositing an oxide layer, a nitride layer and an oxide layer.

6. The method of claim 1, wherein the forming of the nitride layer pattern over the semiconductor substrate comprises:
forming an oxide layer over the semiconductor substrate;
forming a nitride layer over the oxide layer; and
forming the nitride layer pattern and the oxide layer pattern by patterning the nitride layer and the oxide layer by a photolithography process.

7. The method of claim 6, wherein a thickness of the oxide layer pattern and the nitride layer pattern is 1000 Å to 1500 Å.

8. The method of claim 1, wherein the device isolation patterns protrude 1000 Å through 1500 Å from the semiconductor substrate.

9. The method of claim 1, wherein the first insulation layer is an oxide layer.

10. The method of claim 1, wherein the first insulation layer is formed by a high density plasma chemical vapor deposition process.

11. The method of claim 1, wherein the floating gate electrode is formed using a self-alignment process.

12. The method of claim 5, wherein the control gate electrode is formed over the floating gate electrode.

13. An apparatus comprising:
a device isolation pattern defining an active area on a semiconductor substrate;
a floating gate electrode formed over the active area, an upper face of the floating gate electrode being recessed;
an insulation layer pattern formed over the recessed upper face of the floating gate electrode; and
a control gate electrode formed over the insulation layer pattern.

14. The apparatus of claim 13, wherein the device isolation pattern is protruded 1000 Å to 1500 Å from the semiconductor substrate.

15. The apparatus of claim 13, wherein the insulation layer pattern is an oxide layer-nitride layer-oxide layer pattern.

16. The apparatus of claim 13, wherein a height of center portion of the floating gate electrode is lower than a height of edge portion thereof.

17. The apparatus of claim 16, wherein the height of the edge portion of the floating gate electrode is lower than a height of the device isolation pattern.

18. The apparatus of claim 13, wherein an oxide layer is formed between the active area of the semiconductor substrate and the floating gate electrode.

19. The apparatus of claim 13, wherein the floating gate electrode is formed of polysilicon.

20. The apparatus of claim 13, wherein the control gate electrode is formed of polysilicon.
